(19) United States
(12) Patent Application Publication
(10) Pub. No.: US 2006/0064611 A1
(43) Pub. Date: Mar. 23, 2006

(54) Method of testing memory module and memory module

(76) Inventors: Seung-Man Shin, Suwon-si (KR); Byung-Se So, Seongnam-si (KR); Seung-Jin Seo, Suwon-si (KR); Hui-Chong Shin, Seoul (KR)

Correspondence Address: HARNESS, DICKEY & PIERCE, P.L.C., P.O. BOX 8910, RESTON, VA, 20195, US

(21) Appl. No.: 11/227,225

(22) Filed: Sep. 16, 2005

(30) Foreign Application Priority Data
Sep. 22, 2004 (KR) 2004-75920

(51) Int. Cl. G11C 29/00

(52) U.S. Cl. 714/718

(57) ABSTRACT

A method of testing an integrated circuit includes providing a bank access sequence received to a register in the integrated circuit, generating a test pattern sequence based on the bank access sequence, and performing a Built-In Self Test (BIST) operation on the integrated circuit based on the generated test pattern sequence.

### CLAIM FOR PRIORITY

A claim of priority is made to Korean Patent Application No. 2004-75920 filed on Sep. 22, 2004, in the Korean Intellectual Property Office, the entire contents of which are hereby incorporated by reference.

### BACKGROUND OF THE INVENTION

1. Field of the Invention

Example embodiments of the present invention generally relates to a method of testing a memory module and a memory module. In particular, example embodiments of the present invention relate to a method of testing a memory module and a memory module having a Built-In Self Test (BIST) circuit.

2. Description of the Related Art

A memory module with a plurality of memory chips mounted on a Printed Circuit Board (PCB) may be categorized as either a Single Inline Memory Module (SIMM) or a Dual Inline Memory Module (DIMM). A SIMM uses tabs on both sides of the PCB to conduct the same signal. A DIMM uses tabs on both sides of the PCB to conduct different signals. Recently, use of the DIMMs has become more common.

A DIMM can be classified as either a Registered DIMM (RDIMM) or a Fully Buffered DIMM (FBDIMM).

An FBDIMM may be used for high-speed operations with high capacity based on a packet protocol. The use of FBDIMM has become more widespread.

FIG. 1 is a block diagram illustrating a conventional memory module 100.

Referring to FIG. 1, the memory module 100 may include a plurality of memory chips 110 and/or a hub 120.

The hub 120 may include an Advanced Memory Buffer (AMB). The hub 120 may convert a high-speed packet, provided from a system, into a memory command, may interfaces between the memory chips, and/or may perform data transfers with other memory modules. The hub 120 may perform a self-test, such as Built-In Self Test (BIST), on the memory chips during a memory initialization or a system booting process.

A memory test circuit employing a BIST may include a test algorithm implemented on a chip of the memory test circuit. The BIST may perform a memory test with a reduced number of pins, test a high-speed memory module or memory device using a lower-speed test device and implement a parallel memory test.

A disadvantage of a conventional BIST may be that it is not easy to modify a test pattern sequence of a BIST circuit.

FIG. 2 is a schematic block diagram illustrating the hub 120 of the conventional the memory module 100 of FIG. 1.

Referring to FIG. 2, the hub 120 may include a BIST circuit 210 and a memory interface 220.

When a test start signal is applied from an external source, the BIST circuit 210 may generate a test pattern sequence based on a fixed bank access sequence and may perform a test on the memory module 100 based on the generated test pattern sequence. The memory interface 220 may interface between the plurality of memory chips and the hub 120 to test the plurality of memory chips 110 based on the BIST circuit operations. In order to transfer commands, addresses and/or data to the plurality of memory chips 110, the memory interface 220 interfaces between a substrate of the memory module 100 and the hub 120.

As described above, the hub 120 of the conventional memory module 100 performs the BIST operation based on only a fixed bank access sequence. For example, it is not possible to modify a bank access sequence of “D-B-A-C” to a bank access sequence of “A-B-C-D”. In addition, it may not be possible to store all the combinations of the bank access sequences in the hub 120, because, for example, an 8-bank memory device has an 8 factorial (8! or 40,320) bank access sequence combinations.

In a Dynamic Random Access Memory (DRAM) device, defect detection ratio may be varied based on the bank access sequence. For example, a bank access sequence may affect the performance of a 4-bank DRAM during an active operation, a write operation, or a read operation, and the bank access sequence may also have an effect on internal noise levels. These results are associated with an input/output interface and the results may vary depending on different device processes or different manufacturers.

In other words, defect detection ratio may be at its lowest when a bank access sequence is set to “A-B-C-D,”; at other times, the defect detection ratio may be at its lowest when the bank sequence is set to “D-B-C-A.”

As a result, the defect detection ratio of a BIST circuit with a fixed bank access sequence is inconsistent.

### SUMMARY OF THE INVENTION

In an embodiment of the present invention, a method of testing an integrated circuit includes providing a bank access sequence to a register, generating a test pattern sequence based on the bank access sequence by a Built-In Self Test (BIST) circuit, and performing a Built-in Self Test (BIST) operation on the integrated circuit based on the generated test pattern sequence.

In another embodiment of the present invention, a method of testing an integrated circuit includes applying a test signal to a Built-In Self Test (BIST) circuit, providing a bank access sequence to a register, setting a test pattern sequence based on the bank access sequence, and performing a Built-In Self Test (BIST) operation on the integrated circuit.

Yet in another embodiment of the present invention, an integrated circuit includes a bank sequence setting register configured to receive a bank access sequence, and a Built-In Self Test (BIST) circuit configured to generate a test sequence based on the bank access sequence, and configured to perform a Built-In Self Test (BIST) operation on the integrated circuit based on the test sequence.

### BRIEF DESCRIPTION OF THE DRAWINGS

The present invention will become more apparent with the description of example embodiments with reference to the attached drawings in which:

FIG. 1 is a block diagram illustrating a conventional memory module.

FIG. 2 is a block diagram illustrating a hub of the conventional memory module.

FIG. 3 is a flowchart illustrating a method of testing a memory module according to an example embodiment of the present invention.

FIG. 4 is a block diagram illustrating a hub of a memory module according to an example embodiment of the present invention.

FIG. 5 is a flowchart illustrating operations of a Built-In Self Test (BIST) circuit illustrated in FIG. 4 according to an example embodiment of the present invention;

FIG. 6 is a table illustrating a bank address structure of a 4-bank memory device according to an example embodiment of the present invention.

FIG. 7 is a block diagram illustrating a bank sequence setting register of the 4-bank system according to an example embodiment of the present invention.

FIG. 8 is a block diagram illustrating bit configurations of the bank sequence setting register illustrated in FIG. 7 according to an example embodiment of the present invention.

FIG. 9 is a block diagram illustrating an example of a test pattern sequence in a 4-bank memory device according to an example embodiment of the present invention.

FIG. 10 is a block diagram illustrating a test pattern sequence generated based on the bank access sequence illustrated in FIG. 8 according to an example embodiment of the present invention.

FIG. 11 is a table illustrating a bank address structure of an 8-bank memory device according to an example embodiment of the present invention.

FIG. 12 is a block diagram illustrating a bank sequence setting register of an 8-bank memory device according to an example embodiment of the present invention.

FIG. 13 is a block diagram illustrating bit configurations of the bank sequence setting register illustrated in FIG. 12 according to an example embodiment of the present invention.

FIG. 14 is a block diagram illustrating a test pattern sequence generated based on the bank access sequence illustrated in FIG. 13 according to an example embodiment of the present invention.

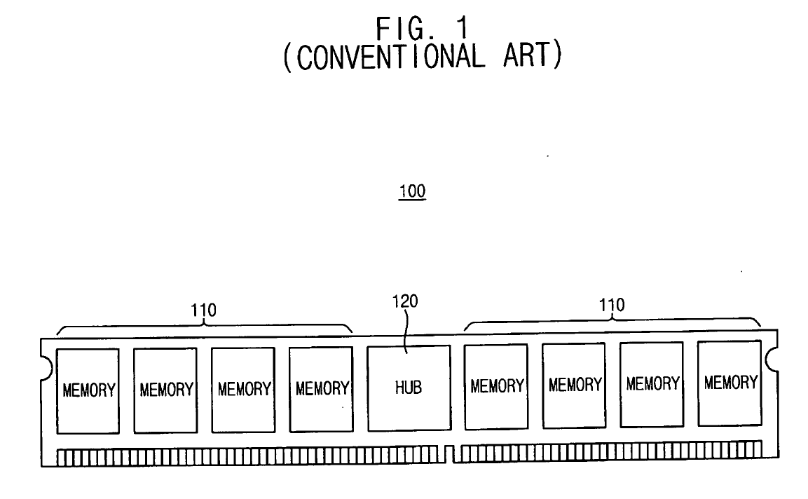

### DETAILED DESCRIPTION OF EXAMPLE EMBODIMENTS OF THE INVENTION

Example embodiments of the present invention are disclosed herein. However, specific structural and functional details disclosed herein are merely representative for purposes of describing example embodiments of the present invention. This invention may, however, may be embodied in many alternate forms and should not be construed as limited to the embodiments set forth herein.

Accordingly, while the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

The terminology used herein is for the purpose of describing particular embodiments only and is not intended to be limiting of the invention. As used herein, the singular forms “a”, “an” and “the” are intended to include the plural forms as well unless the context clearly indicates otherwise. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be farther understood that terms, such as those defined in commonly used dictionaries, should be interpreted as having a meaning that is consistent with their meaning in the context of the relevant art and will not be interpreted in an idealized or overly formal sense unless expressly so defined herein.

It should also be noted that in some alternative implementations, the functions/acts noted in the blocks may occur out of the order noted in the flowcharts. For example, two blocks shown in succession may in fact be executed substantially concurrently or the blocks may sometimes be executed in the reverse order, depending upon the functionality/acts involved.

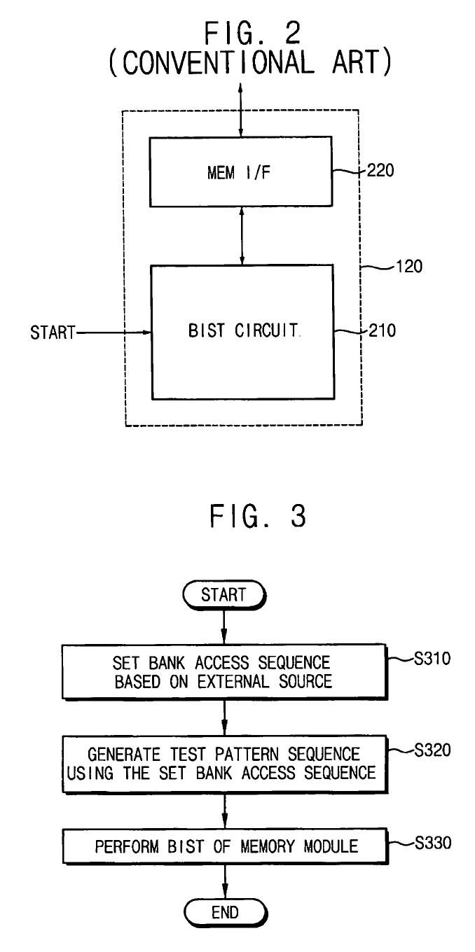

FIG. 3 is a flowchart illustrating a method of testing a memory module according to an example embodiment of the present invention.

It is noted that the external source may refer to a memory module or a source outside of the memory module. The external source may be provided from a user through input/output devices. The bank access sequence may be set using a bank sequence setting register. The bank sequence setting register may be included in a hub of the memory module or a register set of the semiconductor memory device, e.g., memory chip. It is noted that the hub of the memory module includes an Advanced Memory Buffer (AMB). The memory module may be a Fully Buffered Dual Inline Memory Module (FBDIMM).

In a method of testing the memory module according to an example embodiment of the present invention, a bank access sequence may be set based on a sequence provided by an external source (S310).

A test pattern sequence may be generated using the set bank access sequence (S320).

A BIST operation may be performed based on the generated test pattern sequence (S330).

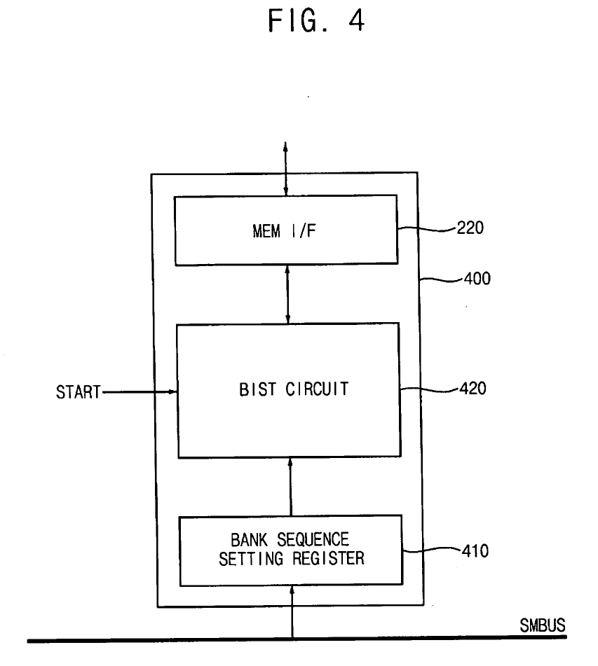

FIG. 4 is a schematic block diagram illustrating a hub 400 of a memory module according to an example embodiment of the present invention.

Referring to FIG. 4, the hub 400 in the memory module may include a bank sequence setting register 410, a BIST circuit 420, and/or a memory interface 220.

The bank sequence setting register 410 may store a bank access sequence provided from an external source.

The bank sequence setting register 410 may receive the bank access sequence through a System Management Bus (SMBus). Thus, the hub 400 can perform the BIST operation using the bank access sequence provided through the SMBus.

A size of the bank sequence setting register 410 depends on the number of banks.

When a test start signal START is applied to the BIST circuit, the BIST circuit 420 may read the bank access sequence from the bank sequence setting register 410 and performs the BIST operation.

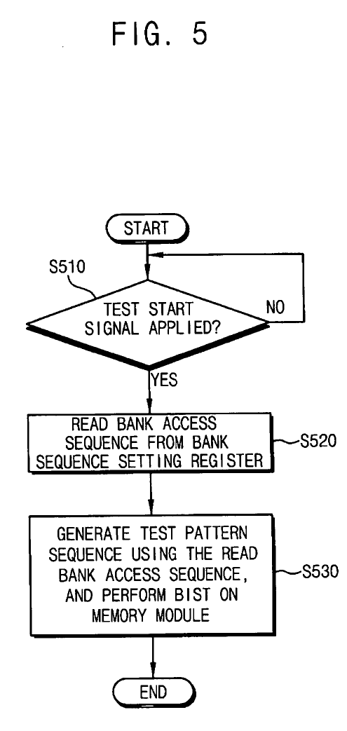

FIG. 5 is a flowchart illustrating operations of a Built-In Self Test (BIST) circuit illustrated in FIG. 4 according to an example embodiment of the present invention.

Referring to FIG. 5, the BIST circuit may determine whether a test start signal has been applied (S510).

If the test start signal has not been applied, the process flow may revert back to S510 and then goes into a wait mode until the test start signal is applied.

If the test start signal has been applied, the BIST circuit 420 may read a bank access sequence from a bank sequence setting register 410 (S520).

The BIST circuit 420 may generate a test pattern sequence using the bank access sequence provided from the bank sequence setting register 410 and performs the BIST operation (S530).

The test pattern sequence may be combinations of an active command, a read command, and a write command. A test algorithm may determine the combinations.

### EXAMPLE EMBODIMENT OF A 4-BANK MEMORY DEVICE

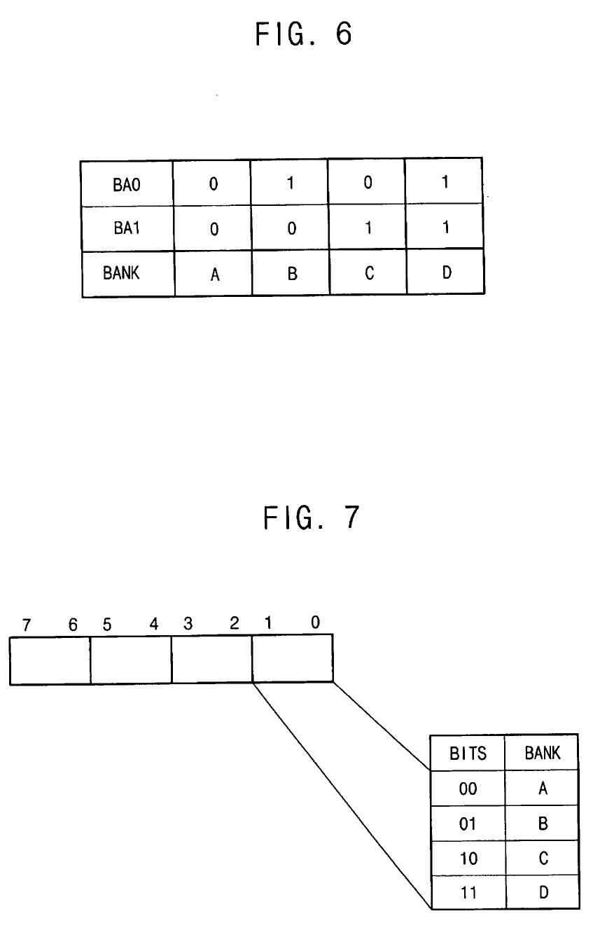

FIG. 6 is a table illustrating a bank address of a 4-bank memory device according to an example embodiment of the present invention.

In the 4-bank memory device, two bits may be used per bank address. Referring to FIG. 6, one bit for a bank address BA0 and another bit for a bank address BA are combined with each other based on four combination rules. As a result, four bank addresses A, B, C and D are designated as illustrated in FIG. 6.

As stated above, any one of the four banks can be designated from the 2-bit bank addresses.

FIG. 7 is a block diagram illustrating a bank sequence setting register of the 4-bank system according to an example embodiment of the present invention.

Referring to FIG. 7, the bank sequence setting register 410 of the 4-bank memory device may be composed of eight bits.

The 8-bit bank sequence setting register 410 may refer to two bits for each of the bank addresses and the four bank addresses A, B, C and D.

That is, the 8-bit bank sequence setting register 410 can store four bank addresses, each bank address composed of two bits. Thus, the 8-bit bank sequence setting register 410 may designate as many as 4 factorial (4! or 24) bank sequence combinations.

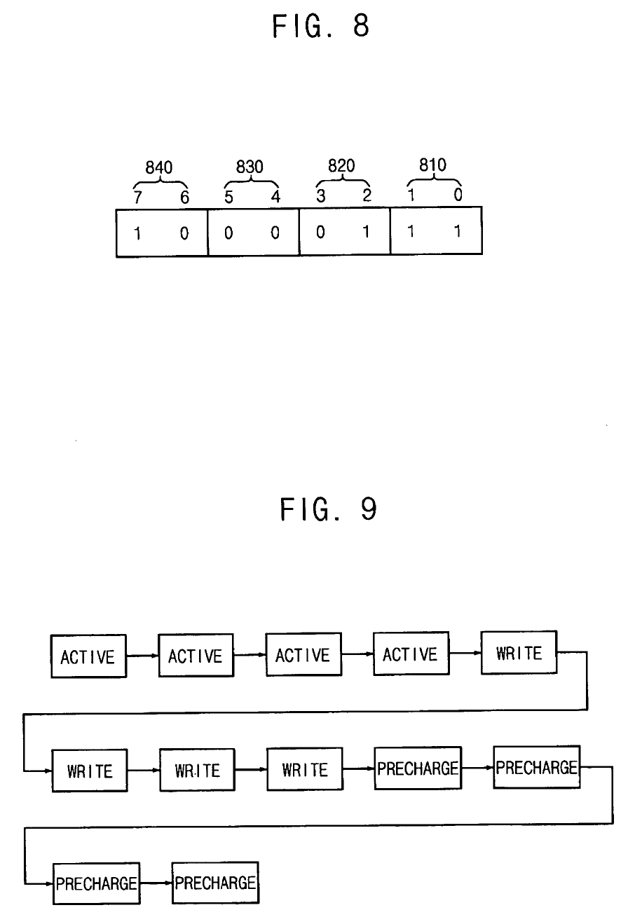

FIG. 8 is a block diagram illustrating bit configurations of the bank sequence setting register illustrated in FIG. 7 according to an example embodiment of the present invention.

Reference numeral 810 is composed of bit values “11,” which represents a first bank address corresponding to bank D.

Reference numeral 820 is composed of bit values “01,” which represents a second bank address corresponding to bank B.

Reference numeral 830 is composed of bit values “00,” which represents a third bank address corresponding to bank A.

Reference numeral 840 is composed of bit values “10,” which represents a fourth bank address corresponding to bank C.

The bank sequence setting register of FIG. 8 may store the bank access sequence of D-B-A-C.

In the bank sequence setting method, a sequence from a Least Significant Bit (LSB) to a Most Significant Bit (MSB) may be used as illustrated in FIG. 8. Alternatively, a sequence from the MSB to the LSB also may be used.

The 8-bit bank sequence setting register can represent all the possible sequences for the 4-bank memory device.

FIG. 9 is a block diagram illustrating an example of a test pattern sequence in the 4-bank memory device according to an example embodiment of the present invention. FIG. 9 shows a test pattern sequence without matching the bank sequence.

Referring to FIG. 9, the test pattern sequence may include an active operation corresponding to each of the four banks, a write operation corresponding to each of the four banks, and a precharge operation corresponding to each of the four banks.

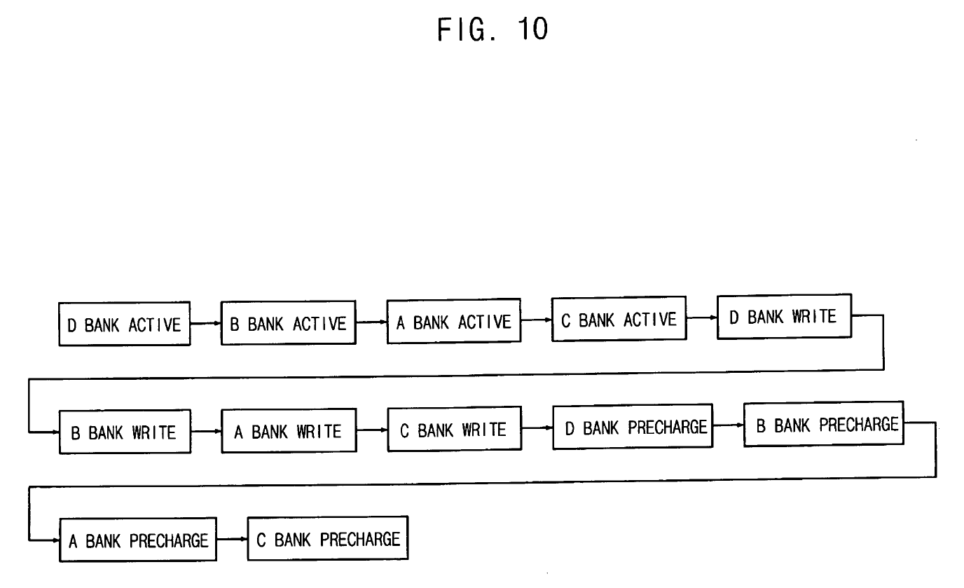

FIG. 10 is a block diagram illustrating a test pattern sequence generated based on the bank access sequence illustrated in FIG. 8 according to an example embodiment of the present invention.

The test pattern sequence shown in FIG. 10 shows the test pattern sequence illustrated in FIG. 9 in more detail.

As shown in FIG. 8, the bank sequence setting register represents the bank access sequence of D-B-A-C, and the test pattern sequences are matched with the bank access sequence. In other words, the test pattern sequence includes the active operations based on the bank access sequence of D-B-A-C, the write operations based on the bank access sequence of D-B-A-C, and the precharge operations based on the bank access sequence of D-B-A-C.

As described above, the 8-bit bank sequence setting register can represent all possible sequences for the 4-bank memory device.

### EXAMPLE EMBODIMENT OF AN 8-BANK MEMORY DEVICE

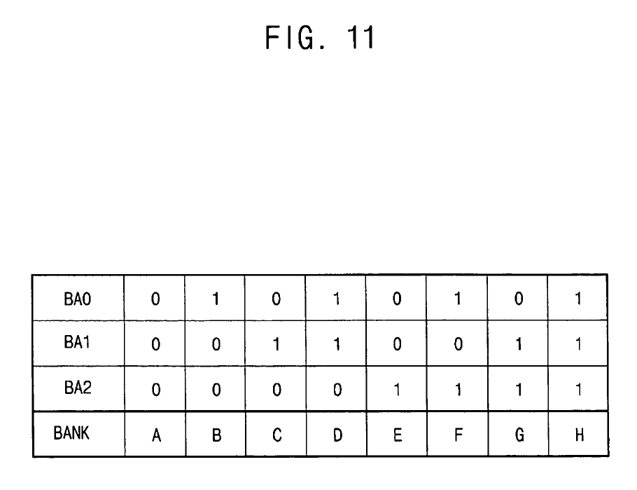

FIG. 11 is a table illustrating a bank address structure of an 8-bank memory device according to an example embodiment of the present invention.

In the 8-bank memory device, three bits may be used for the bank address.

Referring to FIG. 11, one bit for a bank address BA0, another bit for a bank address BA1, and another bit for a bank address BA2. The bits are combined based on eight combination rules. As a result, eight bank addresses A, B, C, D, E, F, C, and H are designated as shown in FIG. 11.

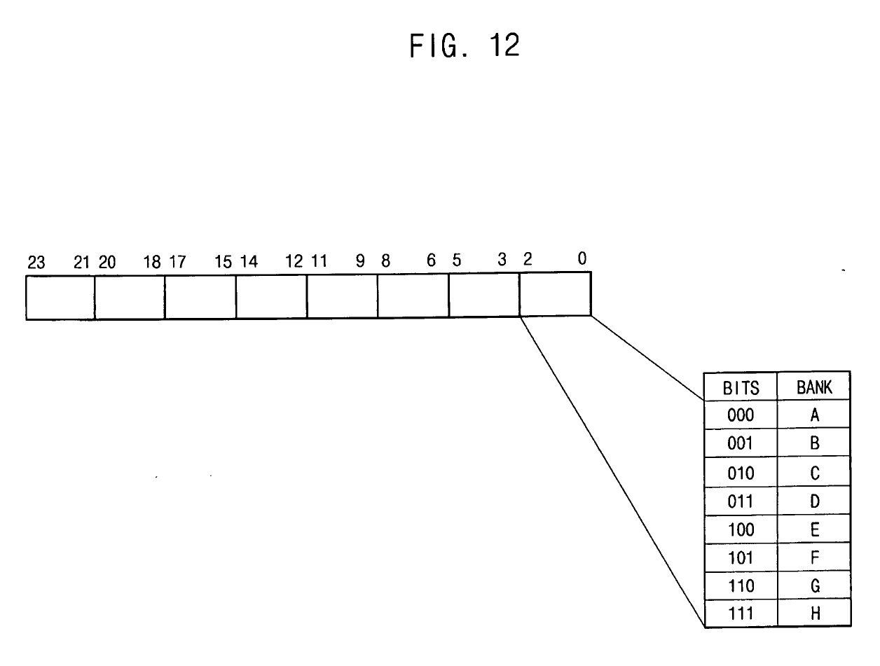

FIG. 12 is a block diagram illustrating a bank sequence setting register of the 8-bank memory device according to an example embodiment of the present invention.

Referring to FIG. 12, the bank sequence setting register of the 8-bank memory device may be composed of 24 bits.

The 24-bit bank sequence setting register refers to three bits for each of the bank addresses and eight bank addresses A, B, C, D, E, F, C, and H. In other words, the 24-bit bank sequence setting register can store eight bank addresses, each bank address composed of three bits.

Thus, the 24-bit bank sequence setting register may designate as many as 8 factorial (8! or 40,320) bank sequence combinations.

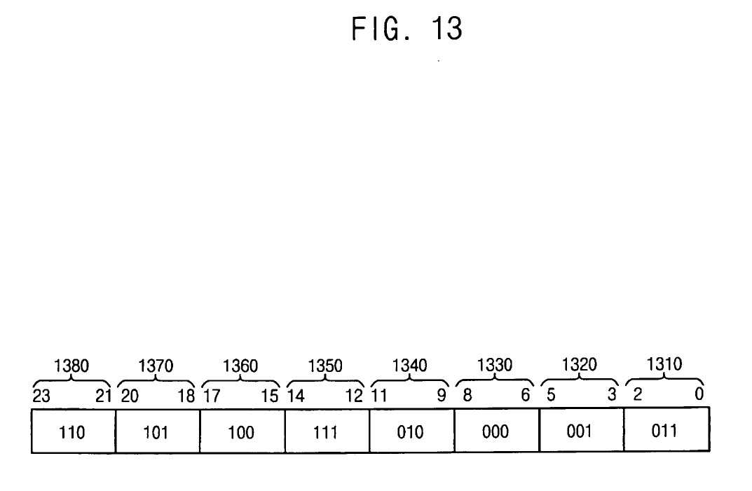

FIG. 13 is a block diagram illustrating bit configurations of the bank sequence setting register illustrated in FIG. 12 according to an example embodiment of the present invention.

Reference numeral 1310 is composed of bit values “011,” which represents a first bank address corresponding to bank D.

Reference numeral 1320 is composed of bit values “001,” which represents a second bank address corresponding to bank B.

Reference numeral 1330 is composed of bit values “000,” which represents a third bank address corresponding to bank A.

Reference numeral 1340 is composed of bit values “010,” which represents a fourth bank address corresponding to bank C.

Reference numeral 1350 is composed of bit values “111,” which represents a fifth bank address corresponding to bank H.

Reference numeral 1360 composed of bit values “100,” which represents a sixth bank address corresponding to bank E.

Reference numeral 1370 composed of bit values “101,” which represents a seventh bank address corresponding to bank F.

Reference numeral 1380 composed of bit values “110,” which represents an eighth bank address corresponding to bank G.

The bank sequence setting register of FIG. 13 may store the bank access sequence of D-B-A-C-H-E-F-G.

In the bank sequence setting method, a sequence from a Least Significant Bit (LSB) to a Most Significant Bit (MSB) may be used as shown in FIG. 13. Alternatively, a sequence from the MSB to the LSB also may be used.

The 24-bit bank sequence setting register can represent all possible sequences of the 8-bank memory device.

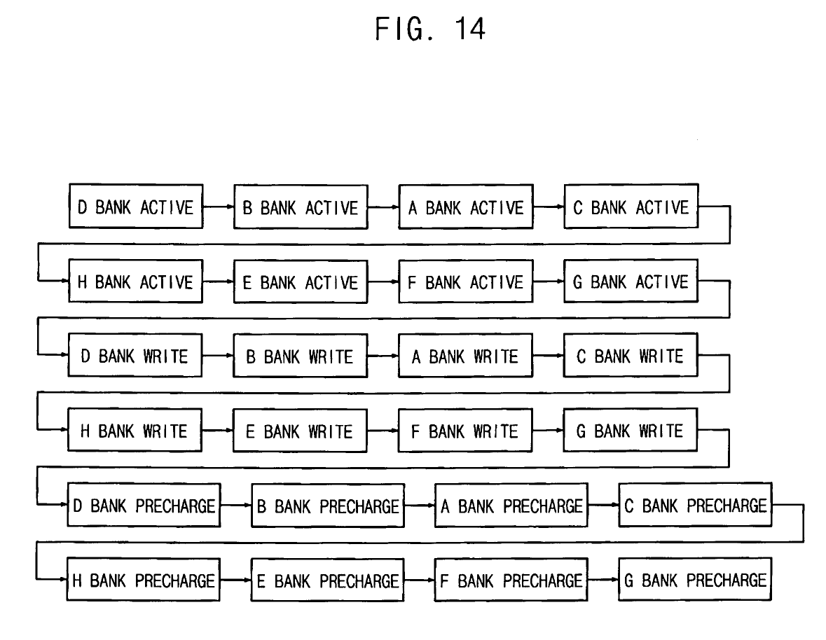

FIG. 14 is a block diagram illustrating a test pattern sequence generated based on the bank access sequence shown in FIG. 13 according to an example embodiment of the present invention.

As shown in FIG. 14, the bank sequence setting register represents the bank access sequence of D-B-A-C-H-E-F-G, and the test pattern sequences are matched with the bank access sequence. That is, the test pattern sequence includes the active operations based on the bank access sequence of D-B-A-C-H-E-F-G, the write operations based on the bank access sequence of D-B-A-C-H-E-F-G, and the precharge operations based on the bank access sequence of D-B-A-C-H-E-F-G.

As described above, the 24-bit bank sequence setting register can represent all the possible sequences of the 8-bank memory device.

In addition, the 24-bit bank sequence setting register may also be adapted to a 4-bank memory device. That is, the 24-bit bank sequence setting register may ignore the highest order bit in each of the 3-bit bank addresses and also ignore the last four bank addresses.

A semiconductor memory device having a BIST circuit may perform a test on a memory module based on a set bank access sequence by setting the bank access sequence to a register included in the semiconductor memory device.

As described above, a hub in the memory module according to the example embodiments of the present invention may perform the BIST operation by variably setting the bank access sequence.

While the example embodiments of the present invention and their advantages have been described in detail with reference to a memory module, it should be understood that various changes, substitutions and alterations may be made herein without departing from the scope of the invention. For example, in addition to a memory module, the present invention may also be implemented in an application specific integrated circuit (ASIC), microcontroller, System on Silicon, System on a Chip, etc.

What is claimed is:

1. A method of testing an integrated circuit, comprising:
providing a bank access sequence to a register;
generating a test pattern sequence based on the bank access sequence by a Built-In Self Test (BIST) circuit; and
performing a Built-In Self Test (BIST) operation on the integrated circuit based on the generated test pattern sequence.

2. The method of claim 1, wherein the bank access sequence is provided from an external source.

3. The method of claim 2, wherein the bank access sequence is provided through a System Management Bus (SMBus) from the external source.

4. The method of claim 1, wherein the integrated circuit includes a memory device.

5. The method of claim 1, wherein the integrated circuit includes a memory module.

6. The method of claims 5, wherein the memory module includes a Fully Buffered Dual Inline Memory Module (FBDIMM).

7. The method of claim 1, wherein the integrated circuit includes an application specific integrated circuit (ASIC), microcontroller, System on Silicon, and System on a Chip.

8. A method of testing an integrated circuit, comprising:
applying a test signal to a Built-In Self Test (BIST) circuit;
providing a bank access sequence to a register;
setting a test pattern sequence based on the bank access sequence; and
performing a Built-In Self Test (BIST) operation on the integrated circuit.

9. The method of claim 8, wherein the bank access sequence is provided from an external source.

10. The method of claim 9, wherein the bank access sequence is provided through a System Management Bus (SMBus).

11. The method of claim 8, wherein the integrated circuit includes a memory device.

12. The method of claim 8, wherein the integrated circuit includes a memory module.

13. The method of claim 8, wherein the integrated circuit is one of an application specific integrated circuit (ASIC), microcontroller, System on Silicon, or System on a Chip.

14. An integrated circuit, comprising:
a bank sequence setting register configured to receive a bank access sequence; and
a Built-In Self Test (BIST) circuit configured to generate a test sequence based on the bank access sequence, and configured to perform a Built-In Self Test (BIST) operation on the integrated circuit based on the test sequence.

15. The integrated circuit of claim 14, wherein a size of the bank sequence setting register equals a number of bits constituting a bank address times a number of banks.

16. The integrated circuit of claim 14, wherein the integrated circuit further comprises a memory module including:
a plurality of memory devices mounted on a substrate; and
a hub including the bank sequence setting register and the BIST circuit.

17. The integrated circuit of claim 16, wherein the hub further comprises an advanced memory buffer (AMB).

18. The integrated circuit of claim 16, wherein the number of the bits constituting the bank address is two and the number of banks is four.

19. The integrated circuit of claim 15, wherein the number of bits constituting the bank address is three, and the number of banks is eight.

20. The integrated circuit of claim 14, wherein the integrated circuit is one of an application specific integrated circuit (ASIC), microcontroller, System on Silicon, or System on a Chip.

21. The integrated circuit of claim 14, wherein the bank sequence setting register receives the bank address sequence from an external source via a system management bus (SMBus).

22. The integrated circuit of claim 14, wherein the integrated circuit includes a memory device.

23. The integrated circuit of claim 14, wherein the integrated circuit includes a memory module.

24. The integrated circuit of claim 14, wherein the memory module includes a Fully Buffered Dual Inline Memory Module (FBDIMM),
